(19) United States
(12) Patent Application Publication
(10) Pub. No.: US 2013/0077266 A1
(43) Pub. Date: Mar. 28, 2013

(54) CONNECTION METHOD AND CONNECTION STRUCTURE OF ELECTRONIC COMPONENT

(71) Applicants: Reiji Tsukao, Tochigi (JP); Tomoyuki Ishimatsu, Tochigi (JP); Hiroki Ozeki, Tochigi (JP)

(72) Inventors: Reiji Tsukao, Tochigi (JP); Tomoyuki Ishimatsu, Tochigi (JP); Hiroki Ozeki, Tochigi (JP)

(73) Assignee: DEXERIALS CORPORATION, Tokyo (JP)

(21) Appl. No.: 13/643,891

(22) PCT Filed: Oct. 26, 2011
(86) PCT No.: PCT/JP2011/074718

§ 371 Date: Dec. 4, 2012

(30) Foreign Application Priority Data
Oct. 28, 2010 (JP) 2010-241865

(51) Int. Cl. H05K 13/04; B32B 27/06; B32B 5/16; H05K 7/06

(52) U.S. Cl. CPC H05K 13/046; H05K 7/06; B32B 27/06; B32B 5/16
USPC 361/749; 361/760; 29/832; 428/418

(57) ABSTRACT

A connection method and a connection structure of electronic components by which high connection reliability can be obtained. An anisotropic conductive film is temporarily disposed, and thermally compressed and bonded, in such manner that a boundary of a circuit protection area and a terminal area of a second electronic component is positioned on a single layer area of the anisotropic conductive film; and the terminal area of the second electronic component is positioned on a double-layer area of the anisotropic conductive film.

### FIELD OF THE INVENTION

The present invention relates to a connection method and a connection structure to connect electronic components via an anisotropic conductive film in which conductive particles are dispersed. The present application claims priority rights to JP Patent Application 2010-241865 filed in Japan on Oct. 28, 2010, which is hereby incorporated by reference.

### BACKGROUND OF THE INVENTION

Conventionally, a substrate, such as a LCD (Liquid Crystal Display) panel and a PD (Plasma Display) panel, and a wiring material, such as a FPC (Flexible Printed Circuit), a COF (Chip On Film), and a TCP (Tape Carrier Package), have been connected using an ACF (Anisotropic Conductive Film). A circuit protection material (solder resist), which protects a circuit, is formed in the wiring material, and the resist layer is compressed and bonded in a state of being in contact with the anisotropic conductive film, whereby connection strength is improved and foreign matter is prevented from entering between wirings. (For example, refer to PTL 1 and PTL 2.).

However, when the circuit protection material is compressed and bonded in the state of being in contact with the anisotropic conductive film, an end of the circuit protection material is clogged with flowing conductive particles, whereby a short-circuit is sometimes caused between connection terminals adjacent each other. Also, a space between the circuit protection material and the substrate is clogged with conductive particles, and removal of resin by pushing is insufficiently performed, whereby connection resistance between the connection terminals sometimes increases.

### PRIOR-ART DOCUMENTS

### Patent Document

PTL 1: Japanese Patent Application Laid-Open No. 2009-135388
PTL 2: Japanese Patent Application Laid-Open No. 2007-41389

### SUMMARY OF THE INVENTION

The present invention is proposed in view of such conventional actual circumstances, and provides a connection method and a connection structure of electronic components by which high connection reliability can be obtained.

In order to solve the above-mentioned problems, a connection method of electronic components according to the present invention comprises a temporarily disposing step, wherein an anisotropic conductive film is temporarily disposed on a first electronic component in which a connection terminal is formed, the anisotropic conductive film having a single layer area constituted by an insulating resin layer which does not contain conductive particles in an insulating resin, and having a double layer constituted by the above-mentioned insulating resin layer and a conductive particle-containing layer in which conductive particles are dispersed in an insulating resin, and a second electronic component is temporarily disposed on said anisotropic conductive film, the second electronic component having a terminal area in which a connection terminal is formed and a circuit protection area in which a circuit protection material protecting a circuit pattern of a connection terminal is formed; and a connecting step, wherein, the first electronic component and the second electronic component are thermally compressed and bonded to connect a connection terminal of the first electronic component and a connection terminal of the second electronic component, wherein, in the temporarily disposing step, the anisotropic conductive film is temporarily disposed in such manner that a boundary between the circuit protection area of the second electronic component and the terminal area is located on the single layer area of the anisotropic conductive film, and the terminal area of the second electronic component is located on the double layer area of the anisotropic conductive film.

A connection structure according to the present invention is characterized in that the first electronic component and the second electronic component are electrically connected by the above-mentioned connection method.

A anisotropic conductive film according to the present invention has a single layer area constituted by an insulating resin layer which does not contain conductive particles in an insulating resin, and a double layer constituted by the insulating resin layer and a conductive particle containing layer in which conductive particles are dispersed in an insulating resin.

A method of producing an anisotropic conductive film according to the present invention is characterized in that an insulating resin layer which does not contain conductive particles in an insulating resin is bonded to a conductive particle containing layer in which conductive particles are dispersed in an insulating resin, to form a single layer area constituted by the insulating resin layer, and a double layer area constituted by the insulating resin layer and the conductive particle containing layer.

### Effects of Invention

The present invention prevents conductive particles from reaching a circuit protection material at the time of thermocompression bonding, thereby preventing an end of the circuit protection material from being clogged with the conductive particles, and preventing a short-circuit from occurring between connection terminals adjacent each other. Also, a space between the circuit protection material and a substrate is prevented from being clogged with conductive particles, and resin is sufficiently removed by pushing, whereby connection resistance between the connection terminals can be prevented from increasing.

### BRIEF DESCRIPTION OF DRAWINGS

FIG. 1A and FIG. 1B illustrate a method for mounting electronic components according to one embodiment of the present invention.

FIG. 2A and FIG. 2B illustrate a conventional method for mounting electronic components.

FIG. 3 is a sectional view illustrating an anisotropic conductive film according to one embodiment of the present invention.

FIG. 4 illustrates an example of a method for producing an anisotropic conductive film.

FIG. 5A to FIG. 5C illustrate methods for mounting electronic components in Examples 1 to 3, respectively.

FIG. 6A to FIG. 6C illustrate methods for mounting electronic components in Comparative Examples 1 to 3, respectively.

FIG. 7A to FIG. 7C illustrate methods for mounting electronic components in Comparative Examples 4 to 6, respectively.

### DETAILED DESCRIPTION OF THE INVENTION

Hereinafter, with reference to the drawings, an embodiment of the present invention will be described in detail in the following order.

1. Connection Method of Electronic Components

2. Anisotropic Conductive Film

3. Examples

### 1. Connection Method of Electronic Components

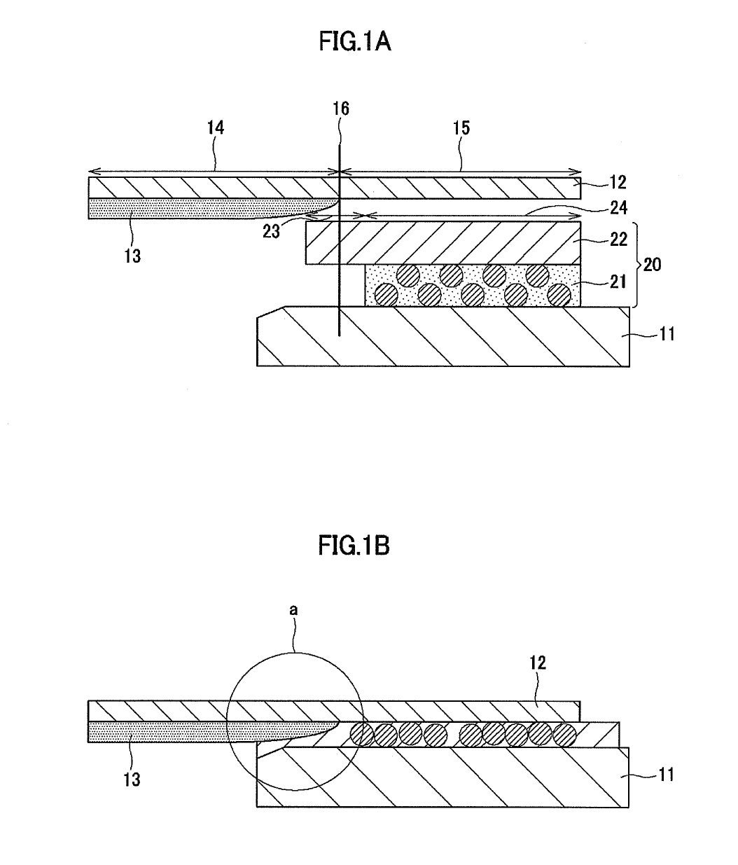

FIG. 1 illustrates a connection method of electronic components according to the present embodiment. The connection method of electronic components shown as an example is such that an anisotropic conductive film 20 having a conductive particle containing layer 21 and an insulating resin layer 22 is interposed between a terminal of a first electronic component 11 and a terminal of a second electronic component 12, and these are heated and compressed, whereby the terminal of the first electronic component 11 and the terminal of the second electronic component 12 are connected.

The first electronic component 11 is, for example, a glass substrate, such as a LCD (Liquid Crystal Display) panel and a PD (Plasma Display) panel, and a terminal for connecting with the second electronic component 12 is formed therein.

The second electronic component 12 is, for example, a wiring material, such as a FPC (Flexible Printed Circuit), a COF (Chip On Film), and a TCP (Tape Carrier Package), and a terminal for connecting with the first electronic component 11 is formed therein. Also, in the second electronic component 12, a circuit protection material (solder resist) 13 for protecting a terminal circuit is formed, and a circuit protection area 14 in which the circuit protection material 13 is formed and a terminal area 15 in which the terminal is exposed are formed.

As mentioned later, the anisotropic conductive film 20 is constituted by the conductive particle containing layer 21 in which conductive particles are dispersed in an insulating resin, and the insulating resin layer 22 in which conductive particles are not contained in an insulating resin. Also, the anisotropic conductive film 20 has a single layer area 23 including a single-layer structure of the insulating resin layer 22, and a double layer area 24 including a double-layer structure of the conductive particle containing layer 21 and the insulating resin layer 22.

The connection method of electronic components according to the present embodiment comprises a temporarily disposing step, wherein the anisotropic conductive film 20 is temporarily disposed on the first electronic component 11, and the second electronic component 12 is temporarily disposed on the anisotropic conductive film 20; and a connecting step, wherein, the first electronic component 11 and the second electronic component 12 are thermally compressed and bonded to connect a connection terminal of the first electronic component 11 and a connection terminal of the second electronic component 12.

In the temporarily disposing step, as illustrated in FIG. 1A, the anisotropic conductive film 20 is temporarily disposed in such manner that a boundary 16 between the circuit protection area 14 and the terminal area 15 of the second electronic component 12 is positioned on the single layer area 23 of the anisotropic conductive film 20, and the terminal area 15 of the second electronic component 12 is positioned on the double-layer area 24 of the anisotropic conductive film 20. More preferably, the anisotropic conductive film 20 is temporarily disposed in such manner that the boundary 16 between the circuit protection area 14 and the terminal area 15 of the second electronic component 12 is positioned in the center portion of the single layer area 24 of the anisotropic conductive film 20. Thus, high connection reliability can be obtained. Particularly, in the case where the first electronic component 11 is a glass substrate of an image display panel while the second electronic component 12 is a flexible wiring substrate, by temporarily arranging the anisotropic conductive film so that the insulating resin layer 22 is positioned at the side of the flexible substrate, particle trapping efficiency can be improved.

In the following connection step, as illustrated in FIG. 1B, connection terminals are connected at a portion a of the boundary 16 between the circuit protection area 14 and the terminal area 15 in the state where conductive particles do not reach the circuit protection material 13. Thus, an end of the circuit protection material 13 is prevented from being clogged with conductive particles, whereby a short circuit can be prevented from occurring between the connection terminals adjacent each other. Also, a space between the circuit protection material 13 and the substrate 11 is prevented from being clogged with conductive particles, and therefore resin is sufficiently removed by pushing, and connection resistance between the connection terminals can be prevented from increasing.

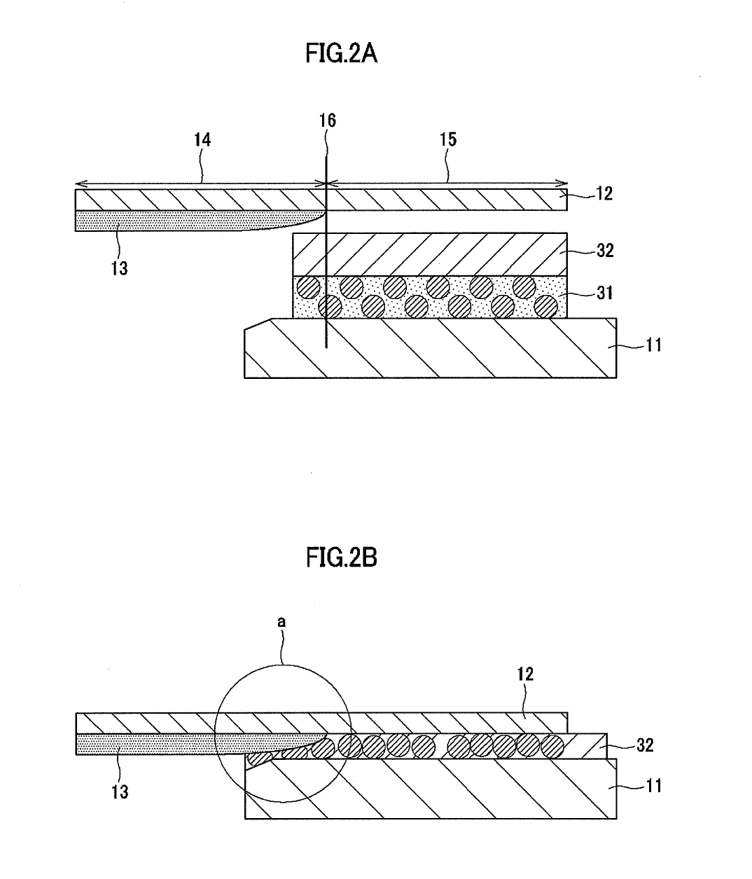

On the other hand, FIG. 2 illustrates a conventional method for mounting electronic components. According to the conventional method of mounting electronic components, as illustrated in FIG. 2A, an anisotropic conductive film including a double-layer structure of a conductive particle containing layer 31 and an insulating resin layer 32 is used, and the conductive particle containing layer 31 exists on a boundary 16 between a circuit protection area 14 and a terminal area 15 of a second electronic component 12. Therefore, as illustrated in FIG. 2B, conductive particles flow at the time of thermocompression bonding, whereby an end of a circuit protection material 13 is clogged with the conductive particles, and a short-circuit is caused between connection terminals adjacent each other. Furthermore, a space between the circuit protection material 13 and a substrate 11 is clogged with the conductive particles, and therefore removal of resin by pushing is insufficiently performed, and connection resistance between the connection terminals increases.

### 2. Anisotropic Conductive Film

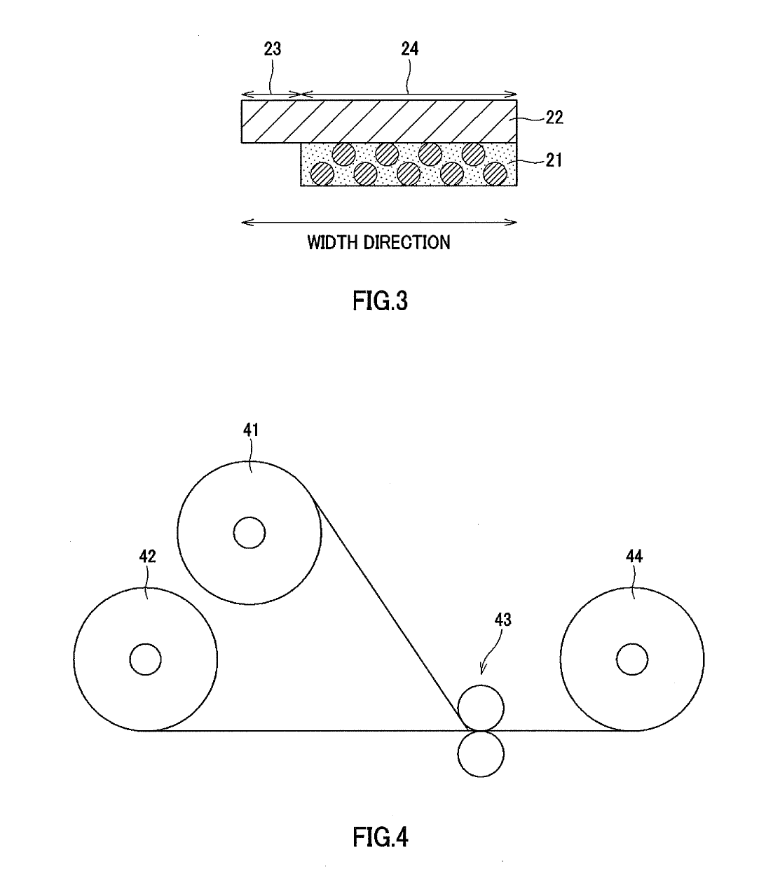

Next, an anisotropic conductive film according to the present embodiment will be described. FIG. 3 is a sectional view illustrating the anisotropic conductive film according to one embodiment of the present invention. This anisotropic conductive film 20 is constituted by a conductive particle containing layer 21 in which conductive particles are dispersed in an insulating resin, and an insulating resin layer 22 in which conductive particles are not contained in an insulating resin.

Also, the anisotropic conductive film 20 has a single layer area 23 including a single-layer structure of the insulating resin layer 22, and a double layer area 24 including a double-layer structure of the conductive particle containing layer 21 and the insulating resin layer 22. The width of the conductive particle containing layer 21 is formed smaller than the width of the insulating resin layer 22, and one end in the width direction of the conductive particle containing layer 21 is bonded at the same position as an end of the insulating resin layer 22. That is, a length in the width direction of the single layer area 23 is equal to a difference between a length in the width direction of the conductive particle containing layer 21 and a length in the width direction of the insulating resin layer 22. Specifically, in the case where a length in the width direction of the insulating resin layer 22 is 1000 to 2000 μm, a difference between a length in the width direction of the conductive particle containing layer 21 and a length in the width direction of the insulating resin layer 22 is preferably 100 to 500 μm, more preferably 100 to 300 μm. When a difference between a length in the width direction of the conductive particle containing layer 21 and a length in the width direction of the insulating resin layer 22 is 100 to 500 μm, it can be prevented that, at the time of thermocompression bonding, the conductive particle containing layer 21 flows, whereby an end of the circuit protection material 13 is clogged with conductive particles.

The conductive particle containing layer 21 of the anisotropic conductive film 20 contains at least a film forming resin, a thermosetting resin, a curing agent, and conductive particles.

The film forming resin is equivalent to a high molecular weight resin having an average molecular weight of 10000 or more, and, from a viewpoint of film formation efficiency, preferably has an average molecular weight of approximately 10000 to 80000. Examples of the film forming resin include various resins, such as phenoxy resin, polyester urethane resin, polyester resin, polyurethane resin, acrylic resin, polyimide resin, and butyral resin, and these resins may be used alone, or two or more kinds of these resins may be used in combination. From viewpoints such as film forming condition and connection reliability, among these resins, phenoxy resin is preferably used.

As the thermosetting resin, epoxy resin, liquid epoxy resin having flowability at normal temperature, or the like may be used alone, or two or more kinds of these resins may be mixed and used. Examples of the epoxy resin include bisphenol A type epoxy resin, bisphenol F type epoxy resin, novolak type epoxy resin, and various kinds of modified epoxy resins, such as rubber and urethane, and these resins may be used alone, or two or more kinds of these resins may be mixed and used. Examples of the liquid epoxy resin include bisphenol type epoxy resin, naphthalene type epoxy resin, biphenyl type epoxy resin, phenol novolak type epoxy resin, stilbene type epoxy resin, triphenol methane type epoxy resin, phenol aralkyl type epoxy resin, naphthol type epoxy resin, dicyclopentadiene type epoxy resin, and triphenyl methane type epoxy resin, and these resins may be used alone, or two or more kinds of these resins may be mixed and used.

The curing agent is not particularly limited and may be suitably selected according to a purpose, and, for example, a latent curing agent which is activated by heating, a latent curing agent which generates free radicals by heating, or the like may be used. Examples of the latent curing agent which is activated by heating include an anionic curing agent, such as polyamine and imidazole, and a cationic curing agent, such as sulfonium salt.

Any electrically good conductor may be used as the conductive particle, and examples of the conductive particle include metal powder, such as copper, silver, and nickel, and a resin particle coated with the above-mentioned metals. Moreover, the conductive particle the whole surface of which is coated with an insulating film may be used.

As another composite to be added, a silane coupling agent is preferably added. Examples of the silane coupling agent include epoxy, amino, mercapto-sulfide, and ureido silane coupling agents. Among these, the epoxy silane coupling agent is preferably used in the present embodiment. Thus, adhesiveness at the interface of an organic material and an inorganic material can be improved. Also, an inorganic filler may be added. Examples of the inorganic filler include silica, talc, titanium oxide, calcium carbonate, and magnesium oxide, and the kind of the inorganic filler is not particularly limited. According to a content of the inorganic filler, flowability can be controlled and particle trapping efficiency can be improved. Furthermore, rubber component or the like may be suitably used in order to reduce the stress of a connected body.

The insulating resin layer 22 of the anisotropic conductive film 20 contains a film forming resin, a thermosetting resin, and a curing agent. A film forming resin, a thermosetting resin, and a curing agent, each of which is equivalent to those used in the conductive particle containing layer 21, may be used. Furthermore, as is the case with the conductive particle containing layer 21, additive composites, such as a silane coupling agent, an inorganic filler, and a rubber component, are preferably added.

The above-mentioned anisotropic conductive film 20 is produced by laminating the conductive particle containing layer 21 and the insulating resin layer 22. Specifically, the producing method comprises a formation step, wherein a resin composite of the conductive particle containing layer 21 is applied on a release base material and dried to form the conductive particle containing layer 21, and the insulating resin layer 22 is formed in the same manner; and a bonding step, wherein the conductive particle containing layer 21 and the insulating resin layer 22 are bonded together.

In the formation step, the resin composite of the conductive particle containing layer 21 or the insulating resin layer 22 is applied on the release base material by using a bar coater, a coating apparatus, or the like, and the resin composite on the release base material is dried using a heat oven, a heating dryer, or the like, to form a layer having a predetermined thickness.

In the bonding step, the conductive particle containing layer 21 and the insulating resin layer 22, each being formed in the formation step and having the predetermined thickness, are bonded together and laminated. For example, as illustrated in FIG. 4, a conductive particle containing resin tape 41 which is produced by rolling up the conductive particle containing layer 21 around a reel, and an insulating resin tape 42 which is produced by rolling up the insulating resin layer 22 being larger by a predetermined width than the conductive particle containing layer 21, around a reel, are bonded together through a bonding apparatus 43, and rolled up, whereby an anisotropy conductive film tape 44 having the single layer area 23 at one side in the width direction thereof is produced, the single layer area 23 constituted by the insulating resin layer 22 having the predetermined width.

Note that the production method is not limited to the one mentioned above, but the insulating resin layer 22 may be formed in such manner that a resin composite of the insulating resin layer 22 is applied on a release base material and dried, and then the conductive particle containing layer 21 may be formed thereon in the same manner. Furthermore, an anisotropic conductive film may be produced in such manner that a film of the conductive particle containing layer 21 and a film of the insulating resin layer 22, each being cut into a rectangle having an arbitrary width, are bonded together.

### EXAMPLES

### 3. Examples

Hereinafter, examples of the present invention will be described. Here, a conductive particle containing layer and an insulating resin layer were produced, and bonded together to produce an anisotropic conductive film having a double-layer structure. Then, a semiconductor device and a substrate were thermally compressed and bonded via the anisotropic conductive film to produce a mounted body, and the number of trapped particles and connection resistance in the mounted body were evaluated. Note that the present invention is not limited to these Examples.

[Production of Conductive Particle Containing Layer]

On a resin composite obtained by compounding 45 parts by mass of phenoxy resin (Product Name: PKHC, manufactured by Tomoe Engineering Co., Ltd.), 50 parts by mass of radical polymerized resin (Product Name: EB-600, manufactured by DAICEL-CYTEC Company Ltd.), 3 parts by mass of hydrophobic silica (Product Name: AEROSIL972, manufactured by EVONIK Industries AG), 2 parts by mass of a silane coupling agent (Product Name: KBM-503, manufactured by Shin-Etsu Chemical Co., Ltd.), and 3 parts by mass of a reaction initiator (Product Name: PERHEXA C, manufactured by NOF Corporation), conductive particles (Product Name: AUL704, manufactured by Sekisui Chemical Co., Ltd.) were dispersed so that a particle density was 6000 particles/mm², and the resulting resin composite was applied on a release base by a bar coater, and the resin composite on the release base was dried by a heat oven, whereby a conductive particle containing layer having a thickness of 8 μm was obtained.

[Production of Insulating Resin Layer]

A resin composite obtained by compounding 55 parts by mass of phenoxy resin (Product Name: PKHC, manufactured by Tomoe Engineering Co., Ltd.), 45 parts by mass of radical polymerized resin (Product Name: EB-600, manufactured by DAICEL-CYTEC Company Ltd.), and 3 parts by mass of a reaction initiator (Product Name: PERHEXA C, manufactured by NOF Corporation) was applied on a release base by a bar coater, and the resin composite on the release base was dried by a heat oven, whereby an insulating resin layer having a thickness of 8 μm was obtained.

[Production of Conductive Film]

The conductive particle containing layer was slit to have a width of 1.2 mm, and rolled up around a reel to produce a conductive particle containing layer tape. Furthermore, the insulating resin layer was slit to have a width of 1.5 mm, and rolled up around a reel to produce an insulating resin layer tape. The conductive particle containing layer tape and the insulating resin layer tape were bonded together through a bonding apparatus, and rolled up, whereby there was produced an anisotropic conductive film which has, at one side of the width direction thereof, a single layer having a width of 0.3 mm and constituted by the insulating resin layer and has a double-layer area having a width of 1.2 mm.

[Production of Mounted Body]

Using an ITO-coated glass (an ITO coat on the whole surface, a glass thickness of 0.7 mm, a chamfer of 0.3 mm), which was a glass substrate, as a first electronic component, and using a COF (50-μm pitch, 8-μm thick Cu—Sn plating, S/R PI type 38-μm thick PI—SperFlex base material), which was a flexible wiring substrate and in which solder resist was formed, as a second electronic component, the ITO-coated glass and the COF were joined together. The anisotropy film was temporarily bonded at a predetermined position on the ITO-coated glass, and the COF was temporarily fixed thereon, and then, using a heat tool having a width of 1.5 mm and coated with 150 μmt of Teflon as a buffer material, joining was performed under joining conditions of 190 degrees C., 4 MPa, and 10 sec, whereby a mounted body was completed.

[Continuity Resistance Test]

For the mounted body, measured was a continuity resistance (initial stage) when 1 mA of current was applied by a four-terminal method, using a digital multimeter (Product Number: Digital. Multimeter 7555, manufactured by Yokogawa Denshikiki Co., Ltd.). Also, measured was a continuity resistance after a TH test (Thermal Humidity Test) was performed under conditions of a temperature of 85 degrees C., a relative humidity of 85%, and 500 hours.

[Short-Circuit Test]

By applying a voltage of 15V to the mounted body, 100 ch of insulation resistance measurement was performed, and the number of short-circuit was counted.

[Adhesive Strength Test]

Using a peel strength tester (TENSILON, manufactured by ORIENTEC Co., Ltd.), measured was a peel strength (N/cm) when the mounted body was peeled at a tensile strength of 50 cm/min in the direction of 90 degrees.

### Example 1

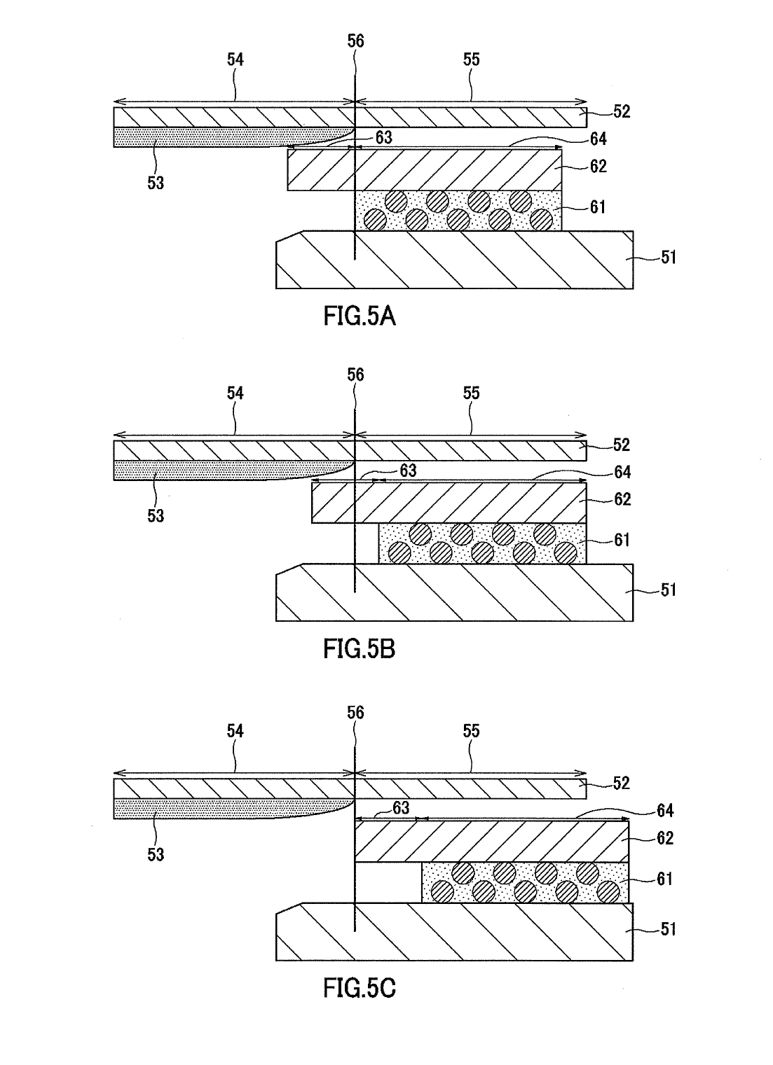

FIG. 5A is a sectional view for explaining a mounting method of electronic components in Example 1. Here, there was used a level-difference anisotropic conductive film, being obtained in such manner that a conductive particle containing layer 61 having a width of 1.2 mm and an insulating resin layer 62 having a width of 1.5 mm were bonded together through a bonding apparatus; and having a single layer area 63 having a width of 0.3 mm and constituted by the insulating resin layer 62, and a double-layer area 64 having a width of 1.2 mm and constituted by a double-layer structure.

As illustrated in FIG. 5A, the anisotropic conductive film was temporarily bonded to coincide a boundary 56 between a circuit protection area 54 and a terminal area 55 with a boundary between the single layer area 63 and the double-layer area 64 of the anisotropic conductive film. That is, the anisotropic conductive film was temporarily bonded to make an overlap of 0.3 mm between the level-difference anisotropic conductive film and a solder resist 53. Then, joining was performed under the above-mentioned joining conditions, whereby a mounted body was obtained, wherein an end of the solder resist 53 was bonded to the level-difference anisotropic conductive film.

An initial continuity resistance of the mounted body was 1.24Ω, and a continuity resistance thereof after a TH test was 1.47Ω. The number of short-circuit was 0, and an adhesive strength was 6.6 N/cm. Table 1 shows these results.

### Example 2

FIG. 5B is a sectional view for explaining a mounting method of electronic components in Example 2. As is the case with Example 1, there was used the level-difference anisotropic conductive film, being obtained in such manner that the conductive particle containing layer 61 having a width of 1.2 mm and the insulating resin layer 62 having a width of 1.5 mm were bonded together through the bonding apparatus; and having the single layer area 63 having a width of 0.3 mm and constituted by the insulating resin layer 62, and the double-layer area 64 having a width of 1.2 mm and constituted by the double-layer structure.

As illustrated in FIG. 5B, the level-difference anisotropic conductive film was temporarily bonded to coincide a boundary 56 between a circuit protection area 54 and a terminal area 55 with a center portion of the single layer area 63 of the anisotropic conductive film. That is, the anisotropic conductive film was temporarily bonded to make an overlap of 0.15 mm between the level-difference anisotropic conductive film and a solder resist 53. Then, joining was performed under the above-mentioned joining conditions, whereby a mounted body was obtained, wherein an end of the solder resist 53 was bonded to the level-difference anisotropic conductive film.

An initial continuity resistance of the mounted body was 1.11Ω, and a continuity resistance thereof after a TH test was 1.32Ω. The number of short-circuit was 0, and an adhesive strength was 6.5 N/cm. Table 1 shows these results.

### Example 3

FIG. 5C is a sectional view for explaining a mounting method of electronic components in Example 3. As is the case with Example 1, there was used the level-difference anisotropic conductive film, being obtained in such manner that the conductive particle containing layer 61 having a width of 1.2 mm and the insulating resin layer 62 having a width of 1.5 mm were bonded together through the bonding apparatus; and having the single layer area 63 having a width of 0.3 mm and constituted by the insulating resin layer 62, and the double-layer area 64 having a width of 1.2 mm and constituted by the double-layer structure.

As illustrated in FIG. 5C, the level-difference anisotropic conductive film was temporarily bonded to coincide a boundary 56 between a circuit protection area 54 and a terminal area 55 with an end portion of the anisotropic conductive film, that is, an end portion of the insulating resin layer 62. Then, joining was performed under the above-mentioned joining conditions, whereby a mounted body was obtained, wherein an end of the solder resist 53 was bonded to the level-difference anisotropic conductive film.

An initial continuity resistance of the mounted body was 1.12Ω, and a continuity resistance thereof after a TH test was 1.34Ω. The number of short-circuit was 0, and an adhesive strength was 5.8 N/cm. Table 1 shows these results.

### Comparative Example 1

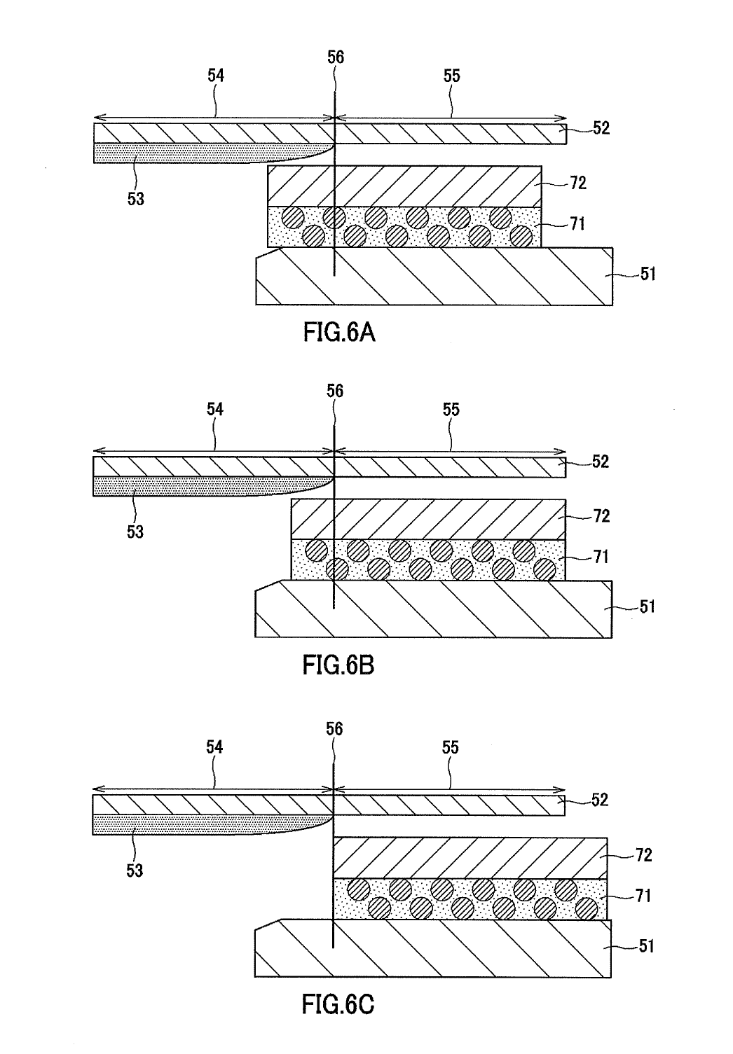

FIG. 6A is a sectional view for explaining a mounting method of electronic components in Comparative Example 1. Here, there was used an anisotropic conductive film, being obtained in such manner that a conductive particle containing layer 71 having a width of 1.5 mm and an insulating resin layer 72 having a width of 1.5 mm were bonded together through a bonding apparatus; and having a width of 1.5 mm and being constituted by a double-layer structure.

As illustrated in FIG. 6A, the anisotropic conductive film was temporarily bonded on a boundary 56 between a circuit protection area 54 and a terminal area 55. Specifically, the anisotropic conductive film was temporarily bonded to make an overlap of 0.3 mm between the anisotropic conductive film and a solder resist 53. Then, joining was performed under the above-mentioned joining conditions, whereby a mounted body was obtained, wherein an end of the solder resist 53 was bonded to the anisotropic conductive film.

An initial continuity resistance of the mounted body was 1.37Ω, and a continuity resistance thereof after a TH test was 1.82Ω. The number of short-circuit was 4, and an adhesive strength was 6.4 N/cm. Table 1 shows these results.

### Comparative Example 2

FIG. 6B is a sectional view for explaining a mounting method of electronic components in Comparative Example 2. As is the case with Comparative Example 1, there was used an anisotropic conductive film, being obtained in such manner that the conductive particle containing layer 71 having a width of 1.5 mm and the insulating resin layer 72 having a width of 1.5 mm were bonded together through the bonding apparatus; and having a width of 1.5 mm and being constituted by the double-layer structure.

As illustrated in FIG. 6B, the anisotropic conductive film was temporarily bonded on a boundary 56 between a circuit protection area 54 and a terminal area 55. Specifically, the anisotropic conductive film was temporarily bonded to make an overlap of 0.15 mm between the anisotropic conductive film and a solder resist 53. Then, joining was performed under the above-mentioned joining conditions, whereby a mounted body was obtained, wherein an end of the solder resist 53 was bonded to the anisotropic conductive film.

An initial continuity resistance of the mounted body was 1.34Ω, and a continuity resistance thereof after a TH test was 1.79Ω. The number of short-circuit was 3, and an adhesive strength was 6.5 N/cm. Table 1 shows these results.

### Comparative Example 3

FIG. 6C is a sectional view for explaining a mounting method of electronic components in Comparative Example 3. As is the case with Comparative Example 1, there was used an anisotropic conductive film, being obtained in such manner that the conductive particle containing layer 71 having a width of 1.5 mm and the insulating resin layer 72 having a width of 1.5 mm were bonded together through the bonding apparatus; and having a width of 1.5 mm and being constituted by the double-layer structure.

As illustrated in FIG. 6C, the anisotropic conductive film was temporarily bonded on a boundary 56 between a circuit protection area 54 and a terminal area 55. Specifically, the anisotropic conductive film was temporarily bonded to coincide the boundary 56 between the circuit protection area 54 and the terminal area 55 with an end portion of the anisotropic conductive film. Then, joining was performed under the above-mentioned joining conditions, whereby a mounted body was obtained, wherein an end of the solder resist 53 was bonded to the anisotropic conductive film.

An initial continuity resistance of the mounted body was 1.22Ω, and a continuity resistance thereof after a TH test was 1.45Ω. The number of short-circuit was 2, and an adhesive strength was 5.9 N/cm. Table 1 shows these results.

### Comparative Example 4

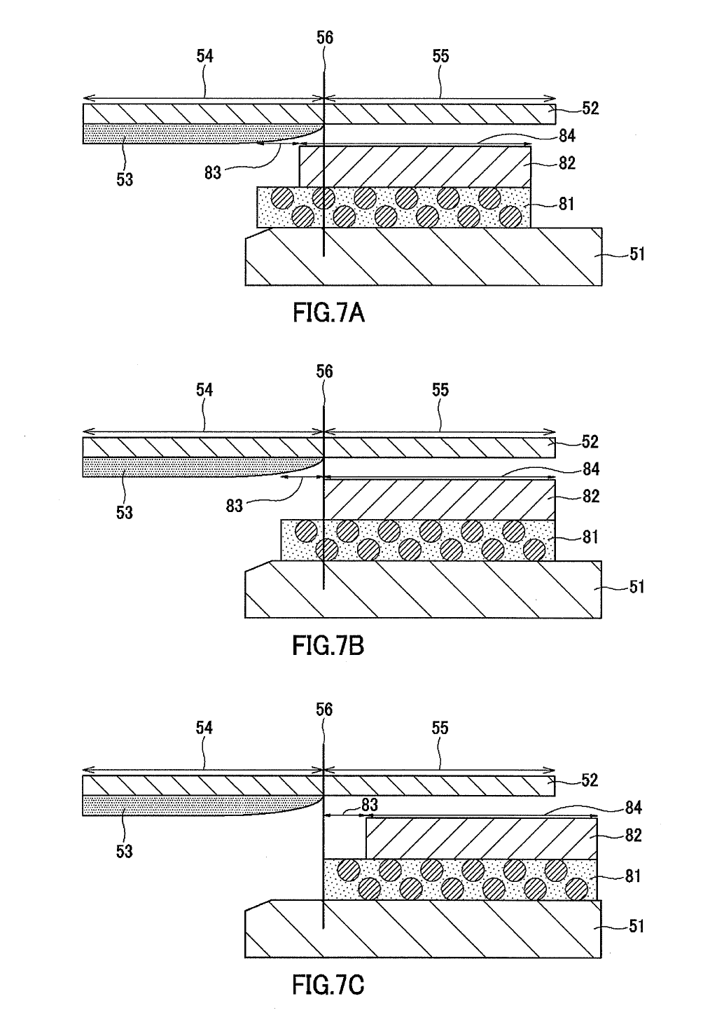

FIG. 7A is a sectional view for explaining a mounting method of electronic components in Comparative Example 4. Here, there was used an anisotropic conductive film, being obtained in such manner that a conductive particle containing layer 81 having a width of 1.5 mm and an insulating resin layer 82 having a width of 1.3 mm were bonded together through a bonding apparatus; and having a single layer area 83 having a width of 0.2 mm and constituted by the conductive particle containing layer 81, and a double-layer area 84 having a width of 1.3 mm and constituted by a double-layer structure.

As illustrated in FIG. 7A, the anisotropic conductive film was temporarily bonded on a boundary 56 between a circuit protection area 54 and a terminal area 55. Specifically, the anisotropic conductive film was temporarily bonded to make an overlap of 0.3 mm between the anisotropic conductive film and a solder resist 53. Then, joining was performed under the above-mentioned joining conditions, whereby a mounted body was obtained, wherein an end of the solder resist 53 was bonded to the anisotropic conductive film.

An initial continuity resistance of the mounted body was 1.23Ω, and a continuity resistance thereof after a TH test was 1.45Ω. The number of short-circuit was 4, and an adhesive strength was 6.4 N/cm. Table 1 shows these results.

### Comparative Example 5

FIG. 7B is a sectional view for explaining a mounting method of electronic components in Comparative Example 5. As is the case with Comparative Example 4, there was used the anisotropic conductive film, being obtained in such manner that the conductive particle containing layer 81 having a width of 1.5 mm and the insulating resin layer 82 having a width of 1.3 mm were bonded together through the bonding apparatus; and having the single layer area 83 having a width of 0.2 mm and constituted by the conductive particle containing layer 81, and the double-layer area 84 having a width of 1.3 mm and constituted by the double-layer structure.

As illustrated in FIG. 7B, the anisotropic conductive film was temporarily bonded to coincide a boundary 56 between a circuit protection area 54 and a terminal area 55 with a boundary between the single layer area 83 constituted by the conductive particle containing layer 81 and the double-layer area 84 of the anisotropic conductive film. That is, the anisotropic conductive film was temporarily bonded to make an overlap of 0.2 mm between the anisotropic conductive film and a solder resist 53. Then, joining was performed under the above-mentioned joining conditions, whereby a mounted body was obtained, wherein an end of the solder resist 53 was bonded to the anisotropic conductive film.

An initial continuity resistance of the mounted body was 1.10Ω, and a continuity resistance thereof after a TH test was 1.31Ω. The number of short-circuit was 4, and an adhesive strength was 5.7 N/cm. Table 1 shows these results.

### Comparative Example 6

FIG. 7C is a sectional view for explaining a mounting method of electronic components in Comparative Example 6. As is the case with Comparative Example 4, there was used the anisotropic conductive film, being obtained in such manner that the conductive particle containing layer 81 having a width of 1.5 mm and the insulating resin layer 82 having a width of 1.3 mm were bonded together through the bonding apparatus; and having the single layer area 83 having a width of 0.2 mm and constituted by the conductive particle containing layer 81, and the double-layer area 84 having a width of 1.3 mm and constituted by the double-layer structure.

As illustrated in FIG. 5C, the anisotropic conductive film was temporarily bonded to coincide a boundary 56 between a circuit protection area 54 and a terminal area 55 with an end portion of the anisotropic conductive film, that is, an end of the conductive particle containing layer 81. Then, joining was performed under the above-mentioned joining conditions, whereby a mounted body was obtained, wherein an end of a solder resist 53 was bonded to the anisotropic conductive film.

An initial continuity resistance of the mounted body was 1.11Ω, and a continuity resistance thereof after a TH test was 1.32Ω. The number of short-circuit was 1, and an adhesive strength was 4.8 N/cm. Table 1 shows these results.

TABLE 1

| | | | | Comparative | Comparative | Comparative | Comparative | Comparative | Comparative |
|---|---|---|---|---|---|---|---|---|---|
| | Example 1 | Example 2 | Example 3 | Example 1 | Example 2 | Example 3 | Example 4 | Example 5 | Example 6 |
| Width relationship | Conductive | Conductive | Conductive | Conductive | Conductive | Conductive | Conductive | Conductive | Conductive |
| between conductive | particle | particle | particle | particle | particle | particle | particle | particle | particle |
| particle containing | containing | containing | containing | containing | containing | containing | containing | containing | containing |
| layer and insulating | layer < | layer < | layer < | layer = | layer = | layer = | layer > | layer > | layer > |
| resin layer | Insulating | Insulating | Insulating | Insulating | Insulating | Insulating | Insulating | Insulating | Insulating |
| | resin layer | resin layer | resin layer | resin layer | resin layer | resin layer | resin layer | resin layer | resin layer |
| Positional | (A) | (B) | (C) | (A) | (B) | (C) | (A) | (B) | (C) |
| relationship | | | | | | | | | |
| between conductive | | | | | | | | | |
| particle containing | | | | | | | | | |
| layer and resist | | | | | | | | | |
| Continuity | 1.24 | 1.11 | 1.12 | 1.37 | 1.34 | 1.22 | 1.23 | 1.10 | 1.11 |
| resistance | | | | | | | | | |
| Continuity | 1.47 | 1.32 | 1.34 | 1.82 | 1.79 | 1.45 | 1.45 | 1.31 | 1.32 |
| resistance | | | | | | | | | |
| (85 degrees C./ | | | | | | | | | |
| 85% RH, 500 h) | | | | | | | | | |
| Number of | 0 | 0 | 0 | 4 | 3 | 2 | 4 | 4 | 1 |
| short-circuits | | | | | | | | | |
| (in 100 ch, the | | | | | | | | | |
| number of | | | | | | | | | |
| measurements) | | | | | | | | | |
| Adhesive strength | 6.6 | 6.5 | 5.8 | 6.4 | 6.5 | 5.9 | 6.4 | 5.7 | 4.8 |
| [N/cm] | | | | | | | | | |

In the anisotropic conductive films of Comparative Examples 1 to 3, in each of which there was no difference in width between the conductive particle containing layer 71 and the insulating resin layer 72, and the anisotropic conductive films of Comparative Examples 4 to 6, in each of which the conductive particle containing layer 81 was larger in width than the insulating resin layer 82, even when the arrangements were made as illustrated in FIG. 6A to FIG. 6C and FIG. 7A to FIG. 7C, short-circuits occurred.

On the other hand, in the anisotropic conductive films of Examples 1 to 3, in each of which the conductive particle containing layer 61 was smaller in width than the insulating resin layer 62, the boundary 56 between the circuit protection area 54 and the terminal area 55 of a COF 52 was arranged on the single layer area 63 of the anisotropic conductive film, and also the terminal area 55 of the COF 52 was arranged on the double-layer area 64 of the anisotropic conductive film, whereby continuity resistance was reduced, occurrence of short-circuit was prevented, adhesive strength was improved, and high connection reliability was achieved.

### REFERENCE SIGNS LIST

11 . . . first electronic component, 12 . . . second electronic component, 13 . . . circuit protection material, 14 . . . circuit protection area, 15 . . . terminal area, 16 . . . boundary, 20 . . . anisotropic conductive film, 21 . . . conductive particle containing layer, 22 . . . insulating resin layer, 23 . . . single layer area, 24 . . . double layer area, 31 . . . conductive particle containing layer, 32 . . . insulating resin layer, 41 . . . conductive particle containing resin tape, 42 . . . insulating resin tape, 43 . . . bonding apparatus, 44 . . . anisotropy conductive film tape, 51 . . . ITO coated glass, 52 . . . COF, 53 . . . solder resist, 54 . . . circuit protection area, 55 . . . terminal area, 56 . . . boundary, 61 . . . conductive particle containing layer, 62 . . . insulating resin layer, 63 . . . single layer area, 64 . . . double layer area, 71 . . . conductive particle containing layer, 72 . . . insulating resin layer, 81 . . . conductive particle containing layer, 82 . . . insulating resin layer, 83 . . . single layer area, and 84 . . . double layer area.

1. A connection method of electronic components comprising:
a temporarily disposing step, wherein
an anisotropic conductive film is temporarily disposed on a first electronic component in which a connection terminal is formed, the anisotropic conductive film having a single layer area constituted by an insulating resin layer which does not contain conductive particles in an insulating resin, and a double layer constituted by the above-mentioned insulating resin layer and a conductive particle containing layer in which conductive particles are dispersed in an insulating resin, and a second electronic component is temporarily disposed on said anisotropic conductive film, the second electronic component having a terminal area in which a connection terminal is formed and a circuit protection area in which a circuit protection material for protecting a circuit pattern of the connection terminal is formed; and
a connecting step, wherein the first electronic component and the second electronic component are thermally compressed and bonded to connect a connection terminal of the first electronic component and a connection terminal of the second electronic component,
wherein, in the temporarily disposing step, the anisotropic conductive film is temporarily disposed in such manner that a boundary between the circuit protection area and the terminal area of the second electronic component is positioned on the single layer area of the anisotropic conductive film, and the terminal area of the second electronic component is positioned on the double layer area of the anisotropic conductive film.

2. The connection method of electronic components according to claim 1, wherein, in the temporarily disposing step, the anisotropic conductive film is temporarily disposed in such manner that the boundary between the circuit protection area and the terminal area of the second electronic component is positioned in a center portion of the single layer area of the anisotropic conductive film.

3. The connection method of electronic components according to claim 1, wherein
the first electronic component is a glass substrate of an image display panel,
the second electronic component is a flexible wiring substrate, and
in the temporarily disposing step, the anisotropic conductive film is temporarily disposed in such manner that the insulating resin layer is positioned at a side of the flexible substrate.

4. A connection structure, wherein the first electronic component and the second electronic component are electrically connected by the connection methods according to claim 1.

5. An anisotropic conductive film, comprising: a single layer area constituted by an insulating resin layer which does not contain conductive particles in an insulating resin; and a double layer constituted by the insulating resin layer and a conductive particle containing layer in which conductive particles are dispersed in an insulating resin.

6. A method of producing an anisotropic conductive film, wherein an insulating resin layer which does not contain conductive particles in an insulating resin is bonded to a conductive particle containing layer in which conductive particles are dispersed in an insulating resin, whereby a single layer area constituted by the insulating resin layer and a double layer area constituted by the insulating resin layer and the conductive particle containing layer are formed.

7. The connection method of electronic components according to claim 2, wherein
the first electronic component is a glass substrate of an image display panel,
the second electronic component is a flexible wiring substrate, and
in the temporarily disposing step, the anisotropic conductive film is temporarily disposed in such manner that the insulating resin layer is positioned at a side of the flexible substrate.

8. A connection structure, wherein the first electronic component and the second electronic component are electrically connected by the connection methods according to claim 2.

9. A connection structure, wherein the first electronic component and the second electronic component are electrically connected by the connection methods according to claim 3.

10. A connection structure, wherein the first electronic component and the second electronic component are electrically connected by the connection methods according to claim 7.
